(19) United States
(12) Patent Application Publication
(10) Pub. No.: US 2007/0238224 A1
(43) Pub. Date: Oct. 11, 2007

(54) PRINTED CIRCUIT BOARD

(75) Inventor: Ning Liu, Shenzhen (CN)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI PRECISION INDUSTRY CO., LTD., Taipei Hsien (TW)

(21) Appl. No.: 11/309,151

(22) Filed: Jun. 28, 2006

(30) Foreign Application Priority Data
Mar. 29, 2006 (CN) 200610060110.2

(51) Int. Cl. H01L 21/00

(52) U.S. Cl. 438/123

(57) ABSTRACT

A printed circuit board includes a signal layer, a pair of signal lines, and a plurality of conductive pads arranged on the signal layer. The conductive pads are located between the two signal lines for reducing crosstalk.

### FIELD OF THE INVENTION

The present invention relates to a printed circuit board (PCB), and more particularly to a PCB for reducing crosstalk of signal lines.

### DESCRIPTION OF RELATED ART

With the rapid improvement in speed of switches in integrated circuits (ICs), demand for better quality transmission characteristics of signal lines is growing.

Referring to FIG. 1 and FIG. 3, a pair of signal lines 12, 14 is arranged on a signal layer 10 of a printed circuit board. Suppose the signal line 12 is a driven line and a source of crosstalk disturbance, and the signal line 14 is undriven and therefore a victim line subject to the disturbance. During signal transmission, crosstalk occurs when there is a coupling of energy from the driven line 12 to the victim line 14. One familiar aspect of crosstalk known as far crosstalk is shown by a curve 1 in FIG. 3 wherein a negative voltage spike is induced in the victim line 14 during the rise time of a signal transmitted through the driven line 12. This is an undesirable effect and needs to be considered carefully in designing the layout of transmission lines on a PCB. There are many methods employed to reduce the phenomenon of crosstalk.

One such method for reducing crosstalk between high-speed signal lines is to keep as much distance between adjacent signal lines as possible. However, with ever increasing density of transmission lines needed on PCBs, this and other similar methods are limited in their application.

What is desired, therefore, is a printed circuit board employing a simple, cost-effective way for reducing crosstalk between signal lines.

### SUMMARY OF THE INVENTION

In one preferred embodiment, a printed circuit board includes a signal layer, a pair of signal lines, and a plurality of conductive pads arranged on the signal layer. The conductive pads are located between the two signal lines for reducing crosstalk.

Other advantages and novel features will become more apparent from the following detailed description of preferred embodiments when taken in conjunction with the accompanying drawings, in which:

### BRIEF DESCRIPTION OF THE DRAWINGS

FIG. 1 is a schematic view of part of a conventional PCB including two transmission lines;

FIG. 2 is a schematic view of part of a PCB in accordance with a preferred embodiment of the present invention including two transmission lines; and

FIG. 3 is a graph of far crosstalk curves of signals transmitted over the transmission lines of the PCBs of FIG. 1 and FIG. 2.

### DETAILED DESCRIPTION OF THE INVENTION

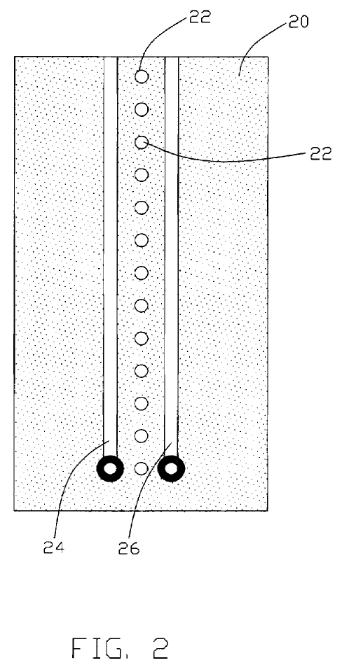

As shown in FIG. 2, in a preferred embodiment of the present invention, a circuit assembly like a printed circuit board includes a signal layer 20, a plurality of conductive pads 22 and a pair of signal lines 24, 26 arranged on the signal layer 20.

The signal lines 24, 26 are used for transmitting high-speed signals. The conductive pads 22, composed of copper in this embodiment, are arranged evenly spaced apart parallel to and between the signal lines 24, 26. Inclusion of the generally circular conductive pads interferes with coupling of energy between the signal lines 24, 26 thereby weakening any induced crosstalk therebetween. That is to say, the conductive pads act as a kind of shield against the negative effects of crosstalk.

The shape and size of the pads 22 are arranged corresponding to practical conditions. The space between every two adjacent pads 22 is according to needed amount of shielding effect as required in PCB design specifications. The PCBs may be single-sided or double-sided boards and single or multi-layer PCBs.

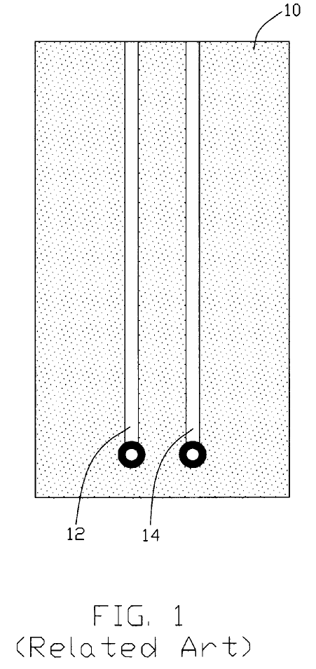

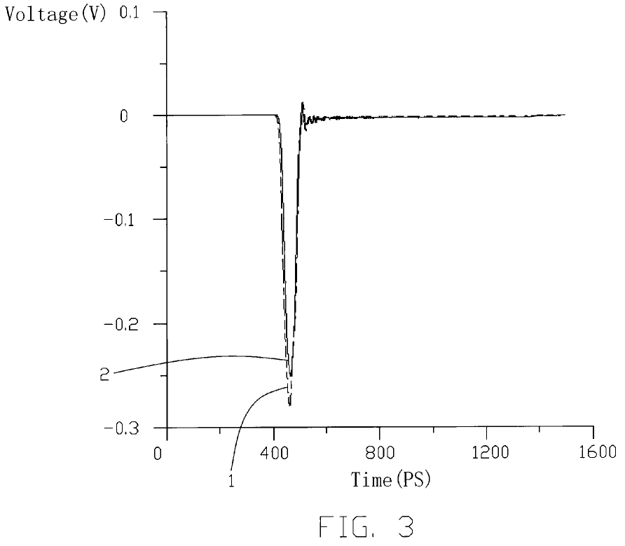

Referring to FIG. 3, it can be seen that when comparing a curve 2 depicting an occurrence of far crosstalk during transmission of a signal using the PCB of the preferred embodiment of FIG. 2, with a curve 1 of an occurrence of far crosstalk using a conventional PCB of FIG. 1 that the magnitude of an induced negative voltage spike during rise time of the transmission is less. When using the PCB of the present invention a similar reduction will be accomplished in other forms of crosstalk as well, such as near crosstalk. In a computer simulation to produce the curves 1, 2 of FIG. 3 the following parameters for the PCBs from FIG. 1 and FIG. 2 were used. “Width of the PCBs” is 200 mil, “length of the PCBs” is 3020 mil, “lengths of the transmission lines 12, 14, 24, 26” is 3000 mil, “widths of the transmission lines 12, 14, 24, 26” is 5 mil, and “distance between the transmission lines 12, 14, 24, 26” is 15 mil. For the PCB of FIG. 2, a radius of each of the pads 22 is 2.5 mil, and space between every two adjacent pads 22 is 25 mil. A unit step signal was input and crosstalk occurred during rise time.

It is believed that the present embodiment and its advantages will be understood from the foregoing description, and it will be apparent that various changes may be made thereto without departing from the spirit and scope of the invention or sacrificing all of its material advantages, the example hereinbefore described merely being a preferred or exemplary embodiment.

What is claimed is:

1. A printed circuit board comprising:
a signal layer;
at least two signal lines arranged proximal each other on the signal layer to transmit signals of the printed circuit board; and
a plurality of conductive pads arranged on the signal layer located between the pair of signal lines.

2. The printed circuit board as claimed in claim 1, wherein the at least two signal lines are high-speed transmission lines.

3. The printed circuit board as claimed in claim 2, wherein spacing between every two adjacent conductive pads is uniform.

4. The printed circuit board as claimed in claim 3, wherein the conductive pads are copper foils.

5. The printed circuit board as claimed in claim 4, wherein the printed circuit board is a single-sided board.

6. The printed circuit board as claimed in claim 4, wherein the printed circuit board is a double-sided board.

7. The printed circuit board as claimed in claim 4, wherein the printed circuit board is a multi-layer board.

8. A method for reducing crosstalk of signal lines of a circuit board, comprising the steps of:
providing a circuit board setting at least two signal lines proximal each other on said circuit board to transmit signals of the circuit board; and
setting a plurality of conductive pads on said circuit board, wherein the conductive pads are located between the at least two signal lines for reducing crosstalk between the at least two signal lines.

9. The method as claimed in claim 8, wherein the at least two signal lines are high-speed transmission lines.

10. The method as claimed in claim 9, wherein space between every two adjacent conductive pads is uniform.

11. The method as claimed in claim 10, wherein the circuit board is a signal-sided board.

12. The method as claimed in claim 10, wherein the circuit board is a double-sided board.

13. The method as claimed in claim 10, wherein the circuit board is a multi-layer board.

14. A circuit assembly comprising:
a signal layer of said circuit assembly;
a first signal line extending along said signal layer for a predetermined distance and configured to transmit signals therethrough for said circuit assembly;
a second signal line extending along said signal layer and arranged beside said first signal line within said predetermined distance, said second signal line configured to transmit another signals therethrough for said circuit assembly; and
a plurality of conductive pads, incapable of signal transmission for said circuit assembly, arranged in said circuit assembly and located between said first and second signal lines within said predetermined distance, said plurality of conductive pads being physically independent from each other and aligned with each other between said first and second signal lines within said predetermined distance.

15. The circuit assembly as claimed in claim 14, wherein said plurality of conductive pads is located at said signal layer respectively.

16. The circuit assembly as claimed in claim 14, wherein said plurality of conductive pads is spaced from each other equidistantly.

17. The circuit assembly as claimed in claim 14, wherein each of said plurality of conductive pads is spaced from said first and second signal lines equidistantly.
